(19) United States
(12) Patent Application Publication
(10) Pub. No.: US 2023/0142791 A1
(43) Pub. Date: May 11, 2023

(54) INORGANIC SOLID OBJECT PATTERN MANUFACTURING METHOD AND INORGANIC SOLID OBJECT PATTERN

(71) Applicant: Toray Industries, Inc., Tokyo (JP)

(72) Inventors: Masao Kamogawa, Otsu-shi, Shiga (JP); Mitsuhito Suwa, Otsu-shi, Shiga (JP); Makoto Hayasaka, Otsu-shi, Shiga (JP)

(73) Assignee: Toray Industries, Inc., Tokyo (JP)

(21) Appl. No.: 17/914,829

(22) PCT Filed: Mar. 15, 2021
(86) PCT No.: PCT/JP2021/010376

§ 371 Date: Sep. 27, 2022

(30) Foreign Application Priority Data
Mar. 31, 2020 (JP) 2020-062553

(51) Int. Cl. C09D 185/00; C09K 13/00; C08G 79/00; G03F 7/11; H01L 21/311

(52) U.S. Cl. CPC C09D 185/00; C09K 13/00; C08G 79/00; G03F 7/11; H01L 21/31116; H01L 21/31144; G03F 7/039

(57) ABSTRACT

A method of producing an inorganic solid pattern is described that includes: a step of coating an inorganic solid with a composition containing a polymetalloxane and an organic solvent; a step of heating the coating film obtained in the coating step, at a temperature of 100° C. or more and 1000° C. or less to form a heat-treated film; a step of forming a pattern of the heat-treated film; and a step of patterning the inorganic solid by etching using the pattern of the heat-treated film as a mask.

### CROSS REFERENCE TO RELATED APPLICATIONS

This application is the U.S. National Phase application of PCT/JP2021/010376, filed Mar. 15, 2021 which claims priority to Japanese Patent Application No. 2020-062553, filed Mar. 31, 2020, the disclosures of these applications being incorporated herein by reference in their entireties for all purposes.

### FIELD OF THE INVENTION

The present invention relates to a method of producing an inorganic solid pattern and to an inorganic solid pattern.

### BACKGROUND OF THE INVENTION

At present, the spread of communications devices such as smartphones and tablet devices is advancing the development of new-generation integrated circuits (ICs) having higher performance and larger functionality. In particular, a semiconductor memory is hopefully expected to contain a memory cell array in the form of a three-dimensional structure so as to achieve higher integration and lower cost. For a process of producing such a semiconductor memory, what is desired is a technology by which an inorganic solid composed of a single layer or a plurality of layers is processed to have a pattern having a high aspect ratio.

One known method of patterning an inorganic solid is a method in which a patterned mask is formed on an inorganic solid to be processed, and then, the inorganic solid is patterned by dry-etching using the mask. When the inorganic solid is dry-etched to have a pattern having a high aspect ratio, the mask is exposed to etching gas for a long time. Accordingly, the mask preferably has high etching resistance.

One generally known mask having high etching resistance is a carbon film deposited by a CVD (Chemical Vapor Deposition) method (for example, see Patent Literature 1).

### PATENT LITERATURE

Patent Literature 1: JP 2017-224823 A

### SUMMARY OF THE INVENTION

However, a method which is described in Patent Literature 1 and in which a carbon film deposited by a CVD method is used as a mask has a problem in that the carbon film takes a long time to deposit. In addition, there is a problem in that, during the processing of an inorganic solid, a carbon film as a mask does not have sufficient dry-etching resistance, and thus, the mask is prone to be shaved, not making it possible to process a pattern having a high aspect ratio. A study was made on increasing the thickness of the deposit of the carbon film in order to form a pattern having a high aspect ratio, but this has a problem in that the carbon film causes a high film stress, and thus applies a large stress to a substrate, causing the substrate to be warped and inhibited from being conveyed with a suction device.

An object of the present invention is to provide the following: a method of producing an inorganic solid pattern, in which the method makes it possible to easily form an inorganic solid pattern having a high aspect ratio; and an inorganic solid pattern.

To solve the above-mentioned problems and achieve the object, a method of producing an inorganic solid pattern according to the present invention is characterized by including: a coating step of coating an inorganic solid with a composition containing a polymetalloxane and an organic solvent; a step of heating a coating film obtained in the coating step, at a temperature of 100° C. or more and 1000° C. or less to form the coating film into a heat-treated film; a step of forming a pattern of the heat-treated film; and a step of patterning the inorganic solid by etching using the pattern of the heat-treated film as a mask.

In addition, the method of producing an inorganic solid pattern according to the present invention is characterized in that, in the above-mentioned invention, the polymetalloxane contains a repeating structure of the following: a metal atom selected from the group consisting of Al, Sc, Ti, V, Cr, Mn, Fe, Co, Ni, Cu, Zn, Ga, Ge, Y, Zr, Nb, Mo, Pd, Ag, In, Sn, Sb, Hf, Ta, W, and Bi; and an oxygen atom.

In addition, the method of producing an inorganic solid pattern according to the present invention is characterized in that, in the above-mentioned invention, the repeating structure of a metal atom and an oxygen atom in the polymetalloxane contains one or more metal atoms selected from the group consisting of Al, Ti, Zr, Hf, and Sn.

In addition, the method of producing an inorganic solid pattern according to the present invention is characterized in that, in the above-mentioned invention, the repeating structure of a metal atom and an oxygen atom in the polymetalloxane includes the metal atoms of Al and Zr.

In addition, the method of producing an inorganic solid pattern according to the present invention is characterized in that, in the above-mentioned invention, the repeating structure of a metal atom and an oxygen atom in the polymetalloxane includes the metal atoms of Al and Zr, wherein the ratio of the Al in all the metal atoms in the polymetalloxane is 10 mol % or more and 90 mol % or less, and the ratio of the Zr in all the metal atoms in the polymetalloxane is 10 mol % or more and 90 mol % or less.

In addition, the method of producing an inorganic solid pattern according to the present invention is characterized in that, in the above-mentioned invention, the repeating structure of the metal atom and the oxygen atom in the polymetalloxane contains the metal atoms of Al and Zr, wherein the ratio of the Al in all the metal atoms in the polymetalloxane is 30 mol % or more and 70 mol % or less, and the ratio of the Zr in all the metal atoms in the polymetalloxane is 30 mol % or more and 70 mol % or less.

In addition, the method of producing an inorganic solid pattern according to the present invention is characterized in that, in the above-mentioned invention, the inorganic solid contains SiO₂ or Si₃N₄.

In addition, the method of producing an inorganic solid pattern according to the present invention is characterized in that, in the above-mentioned invention, the inorganic solid is constituted by one or more materials selected from the group consisting of SiO₂, Si₃N₄, Al₂O₃, TiO₂, ZrO₂, SiC, GaN, GaAs, InP, AlN, TaN, LiTaO₃, BN, TiN, BaTiO₃, InO₃, SnO₂, ZnS, ZnO, WO₃, MoO₃, and Si.

In addition, the method of producing an inorganic solid pattern according to the present invention is characterized in that, in the above-mentioned invention, the polymetalloxane has a weight-average molecular weight of 10,000 or more and 2,000,000 or less.

In addition, the method of producing an inorganic solid pattern according to the present invention is characterized in that, in the above-mentioned invention, the polymetalloxane has a repeating structural unit represented by the following general formula.

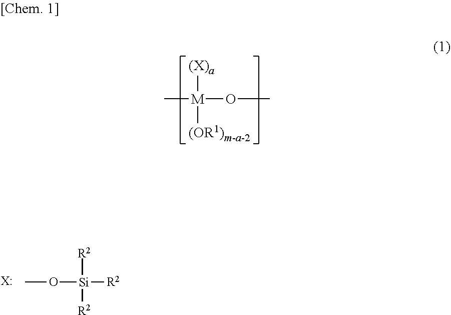

(M represents a metal atom selected from the group consisting of Al, Sc, Ti, V, Cr, Mn, Fe, Co, Ni, Cu, Zn, Ga, Ge, Y, Zr, Nb, Mo, Pd, Ag, In, Sn, Sb, Hf, Ta, W, and Bi. R¹ is arbitrarily selected from a hydrogen atom, an alkyl group having 1 to 12 carbon atoms, or a group having a metalloxane bond. R² is arbitrarily selected from a hydroxy group, an alkyl group having 1 to 12 carbon atoms, an alicyclic alkyl group having 5 to 12 carbon atoms, an alkoxy group having 1 to 12 carbon atoms, an aromatic group having 6 to 30 carbon atoms, a group having a siloxane bond, or a group having a metalloxane bond. When a plurality R¹s and a plurality of R²s exist, the R¹s and the R²s may be the same or different. m is an integer representing the valence of the metal atom M, and a is an integer of 1 to (m−2).)

In addition, the method of producing an inorganic solid pattern according to the present invention is characterized in that, in the above-mentioned invention, the inorganic solid is constituted by one or more materials selected from the group consisting of SiO₂, Si₃N₄, Al₂O₃, TiO₂, and ZrO₂.

In addition, the method of producing an inorganic solid pattern according to the present invention is characterized in that, in the above-mentioned invention, the inorganic solid is a laminate of a plurality of inorganic solid layers.

In addition, an inorganic solid pattern according to the present invention is characterized in that the inorganic solid pattern has a pattern having a pattern depth of 10 μm to 150 μm and contains SiO₂ or Si₃N₄.

In addition, the inorganic solid pattern according to the present invention is characterized in that, in the above-mentioned invention, the pattern has a width of 2 μm or less.

In addition, the inorganic solid pattern according to the present invention is characterized in that, in the above-mentioned invention, the inorganic solid is a laminate of a plurality of inorganic solid layers.

In addition, the inorganic solid pattern according to the present invention is characterized in that, in the above-mentioned invention, the inorganic solid includes a cured film of a polymetalloxane thereon.

The present invention makes it possible to easily form an inorganic solid pattern having a high aspect ratio. In addition, an inorganic solid pattern according to the present invention has a pattern having a pattern depth of 10 μm to 150 μ, and contains SiO₂ or Si₃N₄, and hence, has the effect of enabling a semiconductor memory to have higher integration and cost less.

### DETAILED DESCRIPTION OF EMBODIMENTS OF THE INVENTION

Below, embodiments of a method of producing an inorganic solid pattern and embodiments of an inorganic solid pattern according to the present invention will be described in detail. The present invention is not limited to the below-mentioned embodiments, and can be carried out with various modifications depending on the purpose or usage.

### Embodiment 1

A method of producing an inorganic solid pattern according to an embodiment 1 of the present invention includes: (i) a coating step of coating an inorganic solid with a composition containing a polymetalloxane and an organic solvent; (ii) a step of heating a coating film obtained in the coating step, at a temperature of 100° C. or more and 1000° C. or less to form the coating film into a heat-treated film; (iii) a step of forming a pattern of the heat-treated film; and (iv) a step of patterning the inorganic solid by etching using the pattern of the heat-treated film as a mask.

(Inorganic Solid)

An inorganic solid collectively refers to a solid constituted by a nonmetallic substance other than an organic compound. An inorganic solid to be used in the present invention is subject to no particular limitation, and the inorganic solid preferably contains silicon oxide (SiO₂) or silicon nitride (Si₃N₄). In addition, the inorganic solid is preferably constituted by one or more materials selected from the group consisting of silicon oxide (SiO₂), silicon nitride (Si₃N₄), aluminum oxide (Al₂O₃), titanium oxide (TiO₂), zirconium oxide (ZrO₂), silicon carbide (SiC), gallium nitride (GaN), gallium arsenide (GaAs), indium phosphide (InP), aluminum nitride (AlN), tantalum nitride (TaN), lithium tantalate (LiTaO₃), boron nitride (BN), titanium nitride (TiN), barium titanate (BaTiO₃), indium oxide (InO₃), tin oxide (SnO₂), zinc sulfide (ZnS), zinc oxide (ZnO), tungsten oxide (WO₃), molybdenum oxide (MoO₃), and silicon (Si).

The inorganic solid is preferably constituted by one or more materials selected from the group consisting of SiO₂, Si₃N₄, Al₂O₃, TiO₂, ZrO₂, and Si, and still more preferably constituted by one or more materials selected from the group consisting of SiO₂, Si₃N₄, and Si.

The inorganic solid may be a composite composed of a plurality of inorganic solids. Such an inorganic solid is herein referred to as a composite inorganic solid. Examples of composite inorganic solids include SiOxNy (which is a composite inorganic solid constituted by SiO₂ and Si₃N₄), ITO (indium tin oxide, which is a composite inorganic solid constituted by InO₃ and SnO₂), and the like.

A method of forming an inorganic solid is subject to no particular limitation, and a preferable method is a method in which a material for forming an inorganic solid is deposited on a substrate using a dry process method such as a known sputtering method, a vacuum deposition method (electron beam method), an ion plating method (IP method), or a CVD (Chemical Vapor Deposition) method, or a wet process method such as SOG (Spin on Glass). Among them, a CVD method is preferable because the method can form a thin film with relatively few defects at a relatively low temperature.

The substrate is subject to no particular limitation, and is preferably selected from the group consisting of glass, silicon, quartz, mica, and sapphire. The inorganic solid preferably has a thickness of 0.001 μm to 100 μm.

The inorganic solid is preferably a laminate of a plurality of inorganic solid layers. Examples of a laminate of a plurality of inorganic solid layers include a structure in which two or more different kinds of inorganic solids (for example, an inorganic solid A, an inorganic solid B, and an inorganic solid C) are alternately laminated (for example, ABABAB . . . , ABCABCABC . . . , or the like). The number of layers is preferably 2 or more and 2000 or less.

A method of forming a laminate of a plurality of inorganic solid layers will be described with reference to a laminate in which SiO₂ layers and Si₃N₄ layers are alternately laminated. First, an SiO₂ layer is formed as a first inorganic solid layer by a CVD method. Next, an Si₃N₄ layer is formed as a second inorganic solid layer by a CVD method. On this second inorganic solid layer, another first inorganic solid layer and another second inorganic solid layer are repeatedly laminated in this order to form a laminate.

Such a laminate of a plurality of inorganic solid layers makes it possible that, after being formed into the below-mentioned inorganic solid pattern, the laminate is immersed in an agent in which the solubility is different between the first inorganic solid layer and the second inorganic solid layer, whereby one of the first inorganic solid layer or the second inorganic solid layer is removed. Accordingly, utilizing the empty spaces formed by removing one of the inorganic solids makes it possible to produce a memory cell array having a three-dimensional structure.

The first inorganic solid layer and the second inorganic solid layer each preferably have a thickness of 0.001 μm to 50 μm.

(Polymetalloxane)

A polymetalloxane is a polymer having a repeating structure of a metal atom and an oxygen atom. That is, the polymer has a metal-oxygen-metal bond as a main chain. In a method of producing an inorganic solid pattern according to the embodiment 1 of the present invention, a heat-treated film containing a polymetalloxane is used as a mask when the inorganic solid is patterned by etching.

A polymetalloxane to be used in the present invention contains, as a main chain, a metal atom having low reactivity with an etching gas or an etchant for etching a pattern on the inorganic solid, and thus, has high etching resistance. Accordingly, a heat-treated film containing a polymetalloxane can be used as a mask when the inorganic solid is patterned by etching.

A polymetalloxane is soluble in an organic solvent. Hence, a composition containing a polymetalloxane and an organic solvent, applied and heated, can result in a heat-treated film having high etching resistance. In this manner, a film having high etching resistance can be formed without undergoing a complicated vacuum process such as a CVD method, and hence, the processes can be simplified, compared with a conventional method using a carbon film deposited by a CVD method. In addition, a heat-treated film containing a polymetalloxane has higher etching resistance than the above-mentioned carbon film, and thus, makes it possible to form a desired inorganic solid pattern having a smaller film thickness.

In addition, a polymetalloxane to be used in the present invention causes a lower film stress in the heat-treated film than a carbon film does. Accordingly, when a heat-treated film containing a polysiloxane is formed on an inorganic solid, the stress applied to the substrate and the inorganic solid can be decreased.

The metal atom to be contained in the main chain of the polymetalloxane is preferably selected from the group consisting of Al, Sc, Ti, V, Cr, Mn, Fe, Co, Ni, Cu, Zn, Ga, Ge, Y, Zr, Nb, Mo, Pd, Ag, In, Sn, Sb, Hf, Ta, W, and Bi. Using such a metal atom makes it possible to produce a mask having high etching resistance. The metal atom(s) is/are more preferably one or more selected from the group consisting of Al, Ti, Zr, Hf, and Sn. Using such a metal atom makes it possible that the below-mentioned metal alkoxide to serve as a synthetic raw material for a polymetalloxane is present stably, thus making it easier to obtain a polymetalloxane having a high molecular weight.

The repeating structure of a metal atom and an oxygen atom in the polymetalloxane to be used in the present invention preferably includes the metal atoms of Al and Zr. Containing Al makes it possible that, when the pattern of the heat-treated film is peeled off and removed, the pattern reacts with the below-mentioned liquid chemical and is dissolved. Hence, the rate of dissolution of the heat-treated film is increased, making the peelability good. On the other hand, containing Zr makes it possible to enhance the film density of the heat-treated film, and thus to enhance the etching resistance in the step of patterning the above-mentioned inorganic solid by etching using the below-mentioned pattern of the heat-treated film as a mask.

It is preferable that the repeating structure of a metal atom and an oxygen atom in the polymetalloxane contains the metal atoms of Al and Zr, that the ratio of the Al in all the metal atoms in the polymetalloxane is 10 mol % or more and 90 mol % or less, and that the ratio of the Zr in all the metal atoms in the polymetalloxane is 10 mol % or more and 90 mol % or less. Furthermore, it is more preferable that the ratio of the Al in all the metal atoms in the polymetalloxane is 30 mol % or more and 70 mol % or less, and that the ratio of the Zr in all the metal atoms in the polymetalloxane is 30 mol % or more and 70 mol % or less.

Bringing the ratios of Al and Zr within the above-mentioned ranges makes it possible to achieve both of the following: the etching resistance in the step of patterning the above-mentioned inorganic solid by etching using the below-mentioned pattern of the heat-treated film as a mask; and the peelability with which the pattern of the heat-treated film is peeled off and removed in cases where the heat-treated film pattern remains after the inorganic solid is patterned by etching using the pattern of the heat-treated film as a mask.

The lower limit of the weight-average molecular weight of the polymetalloxane is preferably 10,000 or more, more preferably 20,000 or more, and still more preferably 50,000 or more. The upper limit is preferably 2,000,000 or less, more preferably 1,000,000 or less, still more preferably 500,000 or less. Bringing the weight-average molecular weight within these ranges affords good coating properties. In addition, having the weight-average molecular weight equal to or greater than the lower limit contributes to enhancing the physical properties of the below-mentioned heat-treated film, and thus affording a heat-treated film having excellent crack resistance in particular.

The weight-average molecular weight of the polymetalloxane can be determined by the following method. The polymetalloxane is dissolved in an eluent such that the concentration becomes 0.2 wt % to prepare a sample solution. Subsequently, the sample solution is poured into a column packed with a porous gel and an eluent. The column eluate is detected by a differential refractive index detector and the elution time is analyzed to determine the weight-average molecular weight. N-methyl-2-pyrrolidone containing lithium chloride dissolved therein is suitably used as the eluent.

The polymetalloxane is not limited to any particular repeating structural unit, and preferably has a repeating structural unit represented by the following general formula (1).

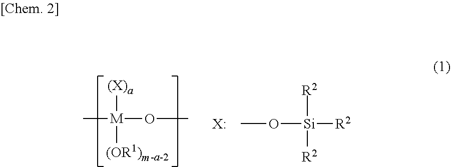

In the general formula (1), M represents a metal atom selected from the group consisting of Al, Sc, Ti, V, Cr, Mn, Fe, Co, Ni, Cu, Zn, Ga, Ge, Y, Zr, Nb, Mo, Pd, Ag, In, Sn, Sb, Hf, Ta, W, and Bi.

Additionally, in the general formula (1), R¹ is arbitrarily selected from a hydrogen atom, an alkyl group having 1 to 12 carbon atoms, or a group having a metalloxane bond. R² is arbitrarily selected from a hydroxy group, an alkyl group having 1 to 12 carbon atoms, an alicyclic alkyl group having 5 to 12 carbon atoms, an alkoxy group having 1 to 12 carbon atoms, an aromatic group having 6 to 30 carbon atoms, a group having a siloxane bond, or a group having a metalloxane bond. When a plurality of R¹s and a plurality of R²s exist, the R¹s and the R²s may be the same or different. m is an integer representing the valence of a metal atom M, and a is an integer of 1 to (m−2).

Examples of the alkyl group having 1 to 12 carbon atoms include a methyl group, an ethyl group, a propyl group, an isopropyl group, a butyl group, an isobutyl group, an s-butyl group, a t-butyl group, a pentyl group, a hexyl group, a heptyl group, an octyl group, a 2-ethylhexyl group, a nonyl group, a decyl group, and the like. In addition, the group having a metalloxane bond means that it is bonded to another metal atom M.

Examples of the alicyclic alkyl group having 5 to 12 carbon atoms include a cyclopentyl group, a cyclohexyl group, a cycloheptyl group, a cyclooctyl group, a cyclononyl group, a cyclodecyl group, and the like.

Examples of the alkoxy group having 1 to 12 carbon atoms include a methoxy group, an ethoxy group, a propoxy group, an isopropoxy group, a butoxy group, an isobutoxy group, an s-butoxy group, a t-butoxy group, a pentoxy group, a hexyloxy group, a heptoxy group, an octoxy group, a 2-ethylhexyloxy group, a nonyl group, a decyloxy group, and the like.

Examples of the aromatic group having 6 to 30 carbon atoms include a phenyl group, a phenoxy group, a benzyl group, a phenylethyl group, a naphthyl group, and the like.

Examples of phenoxy groups having 6 to 30 carbon atoms include a phenoxy group, methylphenoxy group, ethylphenoxy group, propylphenoxy group, methoxyphenoxy group, ethoxyphenoxy group, propoxyphenoxy group, and the like.

Examples of naphthoxy groups having 10 to 30 carbon atoms include a naphthoxy group, methylnaphthoxy group, ethylnaphthoxy group, propylnaphthoxy group, methoxynaphthoxy group, ethoxynaphthoxy group, propoxynaphthoxy group, and the like.

Having the polymetalloxane having the repeating structural unit represented by the general formula (1) makes it possible to form a film mainly composed of a resin containing metal atoms having high electron density in the main chain. This accordingly makes it possible to increase the density of metal atoms in the film, thus making it possible to easily achieve a high film density. In addition, having the polymetalloxane having the repeating structural unit represented by the general formula (1) affords a dielectric having no free electrons, thus making it possible to achieve high transparency and heat resistance.

The polymetalloxane is not limited to any particular method of synthesis, and is preferably synthesized by hydrolyzing at least one of a compound represented by the following the general formula (2) or a compound represented by the general formula (3) as required, and then partially condensing and polymerizing the resulting product. Here, the partial condensation means not to condense all the M-OH of the hydrolyzate, but to leave a part of M-OH in the resultant polymetalloxane. Under the general condensation conditions as mentioned later, generally, M-OH partially remains. The amount of remaining M-OH is not limited.

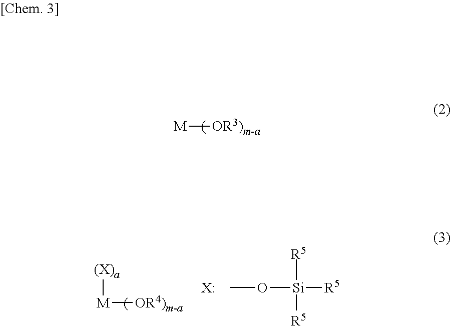

In the general formula (2) and the general formula (3), M represents a metal atom selected from the group consisting of Al, Sc, Ti, V, Cr, Mn, Fe, Co, Ni, Cu, Zn, Ga, Ge, Y, Zr, Nb, Mo, Pd, Ag, In, Sn, Sb, Hf, Ta, W, and Bi.

Additionally, in the general formula (2) or the general formula (3), R³ and R⁴ are arbitrarily selected from a hydrogen atom and alkyl groups having 1 to 12 carbon atoms. R⁵ is arbitrarily selected from a hydroxy group, an alkyl group having 1 to 12 carbon atoms, an alicyclic alkyl group having 5 to 12 carbon atoms, an alkoxy group having 1 to 12 carbon atoms, or an aromatic group having 6 to 30 carbon atoms. When a plurality of R³s, R⁴s, or R⁵s exist, they may be the same or different. Additionally, in the general formula (2) and the general formula (3), m is an integer representing the valence of a metal atom M, and a is an integer of 1 to (m−2).

Examples of a more specific method of synthesizing a polymetalloxane include a method described in WO2019/188834.

(Organic Solvent)

In a method of producing an inorganic solid pattern according to the embodiment 1 of the present invention, a composition for forming a coating film containing a polymetalloxane on an inorganic solid contains an organic solvent, thereby making it possible to adjust the composition to any viscosity. Thus, the composition has good coating film properties.

As the composition, a polymetalloxane solution obtained in the production of a polymetalloxane may be used as it is, or a polymetalloxane solution supplemented with another organic solvent may be used.

The organic solvent to be contained in the composition is subject to no particular limitation, and is preferably the same solvent as that used in the synthesis of a polymetalloxane. An aprotic polar solvent is still more preferable. Using an aprotic polar solvent contributes to enhancing the stability of the polymetalloxane. This enables the composition to cause a smaller increase in viscosity even during long-term storage and to have excellent storage stability.

Specific examples of aprotic polar solvents include acetone, tetrahydrofuran, ethyl acetate, dimethoxyethane, N,N-dimethylformamide, dimethylacetamide, dipropylene glycol dimethyl ether, tetramethylurea, diethylene glycol ethylmethyl ether, dimethyl sulfoxide, N-methylpyrrolidone, γ-butyrolactone, 1,3-dimethyl-2-imidazolidinone, propylene carbonate, NY-dimethylpropyleneurea, N,N-dimethylisobutylamide, and the like.

(Composition)

The solid component concentration of the composition containing a polymetalloxane and an organic solvent is preferably 1 mass % or more and 50 mass % or less, more preferably 2 mass % or more and 40 mass % or less. Bringing the solid component concentration of the composition within the ranges enables the coating film to have good thickness uniformity in the below-mentioned coating step. The solid component concentration of the composition is determined by weighing 1.0 g of the composition in an aluminum cup, heating the polymetalloxane solution at 250° C. for 30 minutes using a hot plate to evaporate the liquid component, and weighing the solid component remaining in the aluminum cup after heating.

The viscosity at 25° C. of the composition containing a polymetalloxane and an organic solvent is preferably 1 mPa·s or more and 1000 mPa·s or less, more preferably 1 mPa·s or more and 500 mPa·s or less, still more preferably 1 mPa·s or more and 200 mPa·s or less. Bringing the viscosity of the composition within the ranges enables the coating film to have good thickness uniformity in the below-mentioned coating step. The viscosity of the composition is determined by making a measurement using a B type viscometer at any rotational speed with the composition having a temperature of 25° C.

The composition containing a polymetalloxane and an organic solvent may contain another component. Examples of such other components include a surfactant, a crosslinking agent, a crosslinking accelerator, and the like.

The surfactant is preferably used for improving the flow property during coating. The surfactant may remain on the heat-treated film.

The surfactant is not limited to any particular type, and examples of a surfactant that can be used include: fluorine-based surfactants such as “MEGAFAC®” F142D, MEGAFAC F172, MEGAFAC F173, MEGAFAC F183, MEGAFAC F444, MEGAFAC F445, MEGAFAC F470, MEGAFAC F475, and MEGAFAC F477 (all of which are manufactured by DIC Corporation) and NBX-15, FTX-218, and DFX-18 (manufactured by Neos Corporation); silicone-based surfactants such as BYK-333, BYK-301, BYK-331, BYK-345, BYK-307, and BYK-352 (manufactured by BYK-Chemie Japan); polyalkylene oxide-based surfactants; and poly(meth)acrylate-based surfactants. Two or more types of these surfactants may be used.

The amount of the surfactant added is preferably 0.001 to 10 parts by weight, and more preferably 0.01 to 1 part by weight, with respect to 100 parts by weight of the polymetalloxane.

The crosslinking agent and the crosslinking accelerator are preferably used for enhancing the film density of the heat-treated film. The crosslinking agent and the crosslinking accelerator are not limited to any particular type, and examples of such an agent or an accelerator that can be used include mono-s-butoxyaluminum diisopropylate, aluminum-s-butyrate, ethylacetoacetate aluminum diisopropylate, aluminum tris(ethyl acetate), alkylacetoaluminum diisopropylate, aluminum monoacetylacetonatebis(ethylacetoacetate), aluminum tris(acetylacetonate), zirconium tris(acetylacetate), zirconium tris(ethylacetoacetate), titanium tris(acetylacetate), titanium tris(ethylacetoacetate), and the like.

The total content of the crosslinking agent and the crosslinking accelerator is preferably 0.1 to 50 parts by weight, more preferably 1 to 20 parts by weight, with respect to 100 parts by weight of the polymetalloxane. The crosslinking agent and the crosslinking accelerator may be used alone or used in combination.

(Coating Step and Step of Providing Heat-Treated Film)

A method of producing an inorganic solid pattern according to the embodiment 1 of the present invention includes: a coating step of applying the above-mentioned composition; and a step of heating a coating film obtained in the coating step, at a temperature of 100° C. or more and 1000° C. or less to form the coating film into a heat-treated film. The heat-treated film thus obtained results in a film mainly composed of a resin having a metal atom having a high electron density in the main chain, thus making it possible to increase the density of metal atoms in the film, which can obtain a high film density easily. In addition, the heat-treated film results in a dielectric containing no free electrons, and thus, can obtain high heat resistance.

As a method of applying the composition, a known method can be used. Examples of the apparatus used for coating include full-surface coating apparatuses such as spin coating, dip coating, curtain flow coating, spray coating, or slit coating, or printing apparatus such as screen printing, roll coating, micro gravure coating, or ink jet.

After coating, heating (pre-baking) may be, if necessary, performed using a heating device such as a hot plate or an oven. Pre-baking is preferably performed at a temperature in the range of 50° C. or more and 150° C. or less for 30 seconds to 30 minutes to form a pre-baked film. Pre-baking makes it possible to have good film thickness uniformity. The film thickness after the pre-baking is preferably 0.1 μm or more and 15 μm or less.

The coating film or the pre-baked film is heated (cured) at a temperature in the range of 100° C. or more and 1000° C. or less, preferably 200° C. or more and 800° C. or less, for 30 seconds to 10 hours using a heating device such as a hot plate or an oven, thus making it possible to obtain a heat-treated film containing a polymetalloxane. Bringing the heating temperature to a value equal to or greater than the lower limit allows the curing of the polymetalloxane to progress, and increases the film density of the heat-treated film. Bringing the heating temperature to a value equal to or lower than the upper limit makes it possible to inhibit the heating from causing damage to a substrate, inorganic solid, and peripheral member.

The thickness of this heat-treated film is preferably 0.1 to 15 μm, more preferably 0.2 to 10 μm. The heat-treated film having a thickness equal to or greater than the lower limit makes it possible that, when the inorganic solid is etched using the below-mentioned pattern of the heat-treated film as a mask, the inorganic solid pattern formed is in the shape of a pattern having excellent straightness in the depth direction. The heat-treated film having a thickness equal to or lower than the upper limit makes it possible to inhibit a stress on the substrate and the inorganic solid.

The film density of the resulting heat-treated film is preferably 1.50 g/cm³ or more and 5.00 g/cm³ or less, more preferably 2.00 g/cm³ or more and 4.00 g/cm³ or less. The heat-treated film having a film density equal to or greater than the lower limit contributes to enhancing the mechanical properties of the below-mentioned pattern of the heat-treated film. Accordingly, the pattern of the heat-treated film can be made less prone to undergo etching damage when the inorganic solid is patterned by etching using the pattern of the heat-treated film as a mask.

The film density of the heat-treated film can be measured by Rutherford backscattering spectroscopy (RBS). The measurement can be made by irradiating the heat-treated film with an ion beam (H⁺ or He⁺⁺) and measuring the energy and intensity of ions scattered backward by Rutherford scattering.

The resulting heat-treated film preferably gives a film stress of 1 MPa or more and 200 MPa or less, more preferably 5 MPa or more and 150 MPa or less. The heat-treated film that gives a film stress equal to or lower than the upper limit makes it possible to inhibit a stress on the substrate and the inorganic solid.

The film stress of the heat-treated film can be measured by the following method. First, a measurement is made of a curvature radius R₁ of a substrate having no heat-treated film formed thereon and having a known biaxial elastic modulus. Next, a heat-treated film is formed on the substrate the curvature radius of which has been measured. A curvature radius R₂ of the substrate having the heat-treated film formed thereon is measured. From R₁ and R₂, a curvature radius change rate R of the substrate is determined. The film stress of the heat-treated film can be calculated using the resulting curvature radius change rate, the biaxial elastic modulus of the substrate, the thickness of the substrate, and the thickness of the heat-treated film.

(Step of Forming Pattern of Heat-Treated Film)

A method of forming a pattern of a heat-treated film is subject to no particular limitation. A preferable method is, for example, a method in which a photoresist pattern is formed on a heat-treated film, or a hard mask pattern composed of a compound selected from the group consisting of SiO₂, Si₃N₄, and carbon, or a composite compound thereof is formed on a heat-treated film, and then, the resulting film is etched.

The photoresist pattern is obtained by forming a photoresist layer on the heat-treated film or the hard mask, and patterning the photoresist layer by photolithography.

The photoresist layer can be obtained by applying a commercially available photoresist. As a coating method, a known method can be used. Examples of the apparatus used for coating include full-surface coating apparatuses such as spin coating, dip coating, curtain flow coating, spray coating, or slit coating, or printing apparatus such as screen printing, roll coating, micro gravure coating or ink jet.

After coating, heating (pre-baking) may be, if necessary, performed using a heating device such as a hot plate or an oven. Pre-baking is preferably performed at a temperature in the range of from 50 to 150° C. for 30 seconds to 30 minutes to form a pre-baked film. Pre-baking makes it possible to have good film thickness uniformity. The film thickness after the pre-baking is preferably 0.1 to 15 μm.

A method of patterning a photoresist layer by photolithography is subject to no particular limitation, and it is preferred that pattern exposure is performed via a desired mask using an ultraviolet visible exposure machine such as a stepper, a mirror projection mask aligner (MPA), a parallel light mask aligner (PLA), followed by development with a known developer for photoresist to obtain a pattern.

As a mask used for pattern exposure, a mask designed to obtain a dot-shaped or square-shaped photoresist pattern of 0.1 μm to 10 μm is preferably used.

The photoresist pattern can be thermally melted, as required. The thermal melting enables the surface of the photoresist pattern to be smoothened. The conditions for thermal melting are subject to no particular limitation, and it is preferred to heat at a temperature in the range of from 50° C. to 300° C. for about 30 seconds to 2 hours using a heating device such as a hot plate or an oven.

A hard mask pattern composed of a compound selected from the group consisting of SiO₂, SiN₃, and carbon, or a composite compound thereof is obtained by depositing the compound, forming the photoresist pattern on the deposit, and etching the deposit.

A compound selected from the group consisting of SiO₂, SiN₃, and carbon, or a composite compound thereof can be deposited using a known method. Examples of such a method include a dry process method such as a sputtering method, a vacuum deposition method (electron beam method), an ion plating method (IP method), or a CVD method, or a wet process method such as spin on glass (SOG). Among them, the CVD method is preferable because it can form a thin film with relatively few defects at a relatively low temperature.

As a method of etching the deposit, a dry-etching method or a wet-etching method can be used.

The dry-etching of the deposit is preferably performed using a reactive ion etching apparatus (RiE apparatus), and using a process gas that is methane trifluoride (CHF₃), methane tetrafluoride (CF₄), oxygen, or a gas mixture thereof. For the wet-etching of the deposit, hydrofluoric acid (HF), nitric acid (HNO₃), ammonium fluoride (NH₄F), or a mixture thereof, diluted with at least one of water or acetic acid (CH₃COOH), is preferably used.

Etching in this manner makes it possible to transcribe the photoresist pattern to the deposit, thus making it possible to process the deposit in pattern form.

A method that can be used to etch the heat-treated film is a dry-etching method or a wet-etching method to be performed using a photoresist pattern or a hard mask pattern as a mask.

The dry-etching of the heat-treated film is preferably performed using a reactive ion etching apparatus (RiE apparatus), and using a process gas that is methane trifluoride (CHF₃), methane tetrafluoride (CF₄), Cl₂ (chlorine), BCl₄ (boron trichloride), CCl₃ (carbon tetrachloride), oxygen, or a gas mixture thereof. For the wet-etching of the heat-treated film, hydrofluoric acid (HF), nitric acid (HNO₃), ammonium fluoride (NH₄F), phosphoric acid (H₃PO₄), or a mixture thereof, diluted with at least one of water or acetic acid (CH₃COOH), is preferably used.

(Step of Patterning Inorganic Solid)

Etching the inorganic solid using the above-mentioned pattern of the heat-treated film as a mask is preferably dry-etching or wet-etching.

The inorganic solid is preferably dry-etched using a reactive ion etching apparatus (RiE apparatus), and using a process gas that is SF₆ (sulfur hexafluoride), NF₃ (nitrogen trifluoride), CF₄ (carbon tetrafluoride), C₂F₆ (ethane hexafluoride), C₃F₈ (propane octafluoride), C₄F₆ (hexafluoro-1,3-butadiene), CHF₃ (trifluoromethane), CH₂F₂ (difluoromethane), COF₂ (carbonyl fluoride), oxygen, or a gas mixture thereof.

For the wet-etching of the inorganic solid, hydrofluoric acid (HF), nitric acid (HNO₃), ammonium fluoride (NH₄F), phosphoric acid (H₃PO₄), or a mixture thereof, diluted with at least one of water or acetic acid (CH₃COOH), is preferably used.

Etching the inorganic solid in such a manner makes it possible to obtain an inorganic solid pattern. The resulting inorganic solid pattern is based on using a high-density heat-treated film pattern as a mask, and thus, enables the inorganic solid pattern to have a high aspect ratio.

The aspect ratio is defined as “the depth direction dimension h/the planar direction dimension w” of the pattern. The rectangular pattern, hole pattern, or line pattern that has an aspect ratio of “1” satisfies “h=w” as the relationship between the depth direction dimension “h” and the planar direction dimension “w”. Herein, a pattern having a high aspect ratio refers to a pattern having an aspect ratio of “0.5” or more.

When the inorganic solid is patterned by etching using the above-mentioned pattern of the heat-treated film as a mask, the rate of etching for the heat-treated film is preferably 100 nm/minute or less, more preferably 30 nm/minute or less, most preferably 5 nm/minute or less. Bringing the rate of etching for the heat-treated film to a value equal to or lower than the upper limit makes the mask less prone to be shaved, and thus, makes it possible to form a deeper inorganic solid pattern. That is, it can be said that the lower the rate of etching for the heat-treated film is, the higher the etching resistance of the heat-treated film as a mask is.

In cases where the heat-treated film pattern remains after the inorganic solid is patterned by etching using the pattern of the heat-treated film as a mask, the pattern of the heat-treated film is preferably peeled off and removed. A preferable method of peeling the heat-treated film off is a method in which the heat-treated film is immersed and dissolved in a liquid chemical given by diluting hydrofluoric acid (HF), nitric acid (HNO₃), ammonium fluoride (NH₄F), phosphoric acid (H₃PO₄), or a mixture thereof with at least one of water or acetic acid (CH₃COOH). It can be said that, when the heat-treated film is immersed in the liquid chemical so as to be peeled off, the larger the rate of dissolution is, the higher (better) the peelability is. The rate of dissolution is preferably 10 nm/minute or more, more preferably 40 nm/minute or more, most preferably 80 nm/minute or more. Such a higher peelability makes it possible to shorten the time while the heat-treated film is immersed in the peeling liquid for the pattern of the heat-treated film to be peeled off, and thus, makes it possible to shorten the process time further.

### Embodiment 2

(Inorganic Solid Pattern)

An inorganic solid pattern according to an embodiment 2 of the present invention has the below-mentioned characteristic structure. That is, the inorganic solid pattern according to this embodiment 2 has a pattern having a pattern depth of 10 μm to 150 μm. In addition, the inorganic solid pattern according to this embodiment 2 contains SiO₂ or Si₃N₄.

For example, the inorganic solid pattern according to this embodiment 2 can be formed by a method including: a coating step of coating an inorganic solid with a composition containing a polymetalloxane and an organic solvent; a step of heating a coating film obtained in the coating step, at a temperature of 100° C. or more and 1000° C. or less to form the coating film into a heat-treated film; a step of forming a pattern of the heat-treated film; and a step of patterning the inorganic solid by etching using the pattern of the heat-treated film as a mask.

Having a pattern having a pattern depth of 10 μm to 150 μm makes it possible to form more memory cells in the vertical direction in the resulting memory cell array having a three-dimensional structure. This makes it possible to enhance the density of the memory cells, thus making it possible to achieve cost reduction. In addition, having the inorganic solid pattern containing SiO₂ or Si₃N₄ enables the resulting memory cell array to have a three-dimensional structure.

An inorganic solid pattern according to the embodiment 2 of the present invention preferably has a pattern width of 2 μm or less, more preferably 1 μm or less, still more preferably 0.5 μm or less. When the inorganic solid pattern is used in applications for a memory cell array having a three-dimensional structure, memory cells are formed in the pattern. Because of this, having a pattern width within the range makes it possible to form more memory cells in the horizontal direction. This makes it possible to enhance the density of the memory cells, thus making it possible to achieve cost reduction.

For an inorganic solid pattern according to the embodiment 2 of the present invention, it is preferable that the inorganic solid is a laminate of a plurality of inorganic solid layers. Such a laminate of a plurality of inorganic solid layers is immersed in an agent in which the solubility is different among the inorganic solids. Thus, (an) inorganic solid(s) can be removed selectively. Accordingly, utilizing the empty spaces formed by removing one of the inorganic solids makes it possible to produce a memory cell array having a three-dimensional structure.

In the inorganic solid pattern according to the embodiment 2 of the present invention, the inorganic solid preferably includes a cured film of a polymetalloxane thereon. Having the inorganic solid including a cured film of a polymetalloxane thereon allows the cured film of a polymetalloxane to function as an insulation film having high etching resistance, and thus, making it easy to further process the inorganic solid pattern to thereby form a memory array having a three-dimensional structure.

In this regard, the same inorganic solid as in the above-mentioned inorganic solid pattern according to the embodiment 1 can be used as an inorganic solid for the inorganic solid pattern according to the embodiment 2 of the present invention.

(Applications of Inorganic Solid Pattern)

An inorganic solid pattern obtained by a method of producing an inorganic solid pattern according to the present invention can be used as a semiconductor memory. In particular, the inorganic solid pattern is suitable for a NAND type flash memory that desirably has an inorganic solid pattern having a high aspect ratio.

### Examples

The present invention will be described more specifically by way of Synthesis Examples and Examples, but the present invention is not limited to these Examples.

(Solid Component Concentration)

In each of Synthesis Examples and Examples, the solid component concentration of a polymetalloxane solution was determined by weighing 1.0 g of the polymetalloxane solution in an aluminum cup, heating the polymetalloxane solution at 250° C. for 30 minutes using a hot plate to evaporate the liquid component, and weighing the solid component remaining in the aluminum cup after heating.

(Infrared spectroscopic analysis) An analysis by Fourier transform infrared spectroscopy (hereinafter referred to as FT-IR for short) was performed by the following method. First, using a Fourier transform infrared spectrometer (FT 720, manufactured by Shimadzu Corporation), two silicon wafers superposed one upon another were measured and used as a baseline. Next, one drop of a metal compound or a solution thereof was dropped on a silicon wafer and the silicon wafer was sandwiched by another silicon wafer, and the sample thus obtained was used as a measurement sample. An absorbance of the compound or a solution thereof was calculated from the difference between the absorbance of the measurement sample and the absorbance of the baseline, and the absorption peak was read.

(Measurement of Weight-Average Molecular Weight)

The weight-average molecular weight (Mw) was determined by the following method. Lithium chloride as an eluent was dissolved in N-methyl-2-pyrrolidone to prepare a 0.02 mol/dm³ lithium chloride/N-methyl-2-pyrrolidone solution. A polymetalloxane was dissolved in the eluent in the concentration of 0.2 wt %, and the solution thus obtained was used as a sample solution. A porous gel column (each one of TSK gels, α-M and α-3000, manufactured by Tosoh Corporation) was packed with the eluent at a flow rate of 0.5 mL/min, and 0.2 mL of the sample solution was injected into the column. The column eluate was detected by a differential refractive index detector (Model RI-201, manufactured by Showa Denko K.K.), and the elution time was analyzed to determine the weight-average molecular weight (Mw).

(Measurement of Film Density)

The film density of a heat-treated film is determined using a Pelletron 3 SDH (manufactured by National Electrodtstics Corp.) to irradiate a heat-treated film with an ion beam, and analyze scattered ion energy. In this regard, the measurement conditions were as follows: ⁴He⁺⁺ as an incident ion; an incident energy of 2300 keV; an angle of incidence of 0 deg; a scattering angle of 160 deg; a sample current of 8 nA; a beam diameter of 2 mm; and 48 μC as the amount of irradiation.

(Measurement of Film Stress)

The film stress of a heat-treated film was determined by using a thin film stress measurement apparatus FTX-3300-T (manufactured by Toho Technology Co., Ltd.) to measure the curvature radius R₁ of a 6-inch silicon wafer, then forming a heat-treated film on the wafer, and measuring the curvature radius R₂ of the substrate having the heat-treated film formed thereon. From R₁ and R₂, the curvature radius change rate R of the wafer was determined. The R obtained, the biaxial elastic modulus of the wafer, the thickness of the substrate, and the thickness of the heat-treated film were used to calculate the film stress of the heat-treated film. In this regard, the biaxial elastic modulus of the wafer was 1.805×10¹¹ Pa.

### Synthesis Example 1

In Synthesis Example 1, a polymetalloxane (PM-1) solution was synthesized. Specifically, 35.77 g (0.10 mol) of tri-n-propoxy(trimethylsiloxy)zirconium and 30.66 g of N,N-dimethylisobutylamide (hereinafter referred to as DMIB for short) as a solvent were mixed to obtain a solution 1. In addition, 5.40 g (0.30 mol) of water, 50.0 g of isopropyl alcohol (hereinafter referred to as IPA for short) as a water-diluted solvent, and 1.85 g (0.01 mol) of tributylamine as a polymerization catalyst were mixed to obtain a solution 2.

In a three-necked flask having a capacity of 500 ml, the entire amount of the solution 1 was charged, and the flask was immersed in an oil bath at 40° C., followed by stirring for 30 minutes. Thereafter, the entire amount of the solution 2 was charged in a dropping funnel for the purpose of hydrolysis, and then added in the flask over 1 hour. During the addition of the solution 2, precipitation did not occur in the liquid in the flask, and it was a uniform colorless and transparent solution. After the addition, the mixture was stirred for additional 1 hour to obtain a hydroxyl group-containing metal compound. Thereafter, for the purpose of polycondensation, the oil bath was heated to 140° C. over 30 minutes. One hour after starting of temperature rise, the internal temperature of the solution reached 100° C., and the mixture was heated with stirring for 2 hours (internal temperature was 100 to 130° C.). During the reaction, IPA, n-propanol, and water were distilled. During heating with stirring, precipitation did not occur in the liquid in the flask, and it was a uniform transparent solution.

After completion of the heating, the liquid in the flask was cooled to room temperature to obtain a polymetalloxane solution. The appearance of the polymetalloxane solution obtained was pale yellow transparent. The solid component concentration of the polymetalloxane solution obtained was 39.8 mass %. Then, DAM was added such that the solid component concentration became 20.0% to obtain a polymetalloxane (PM-1) solution.

Analysis of the polymetalloxane (PM-1) solution by FT-IR revealed that an absorption peak of Zr—O—Si (968 cm⁻¹) was observed, and thus the polymetalloxane was a polymetalloxane having a trimethylsiloxy group. The weight-average molecular weight (Mw) of the polymetalloxane (PM-1) was 500,000 in terms of polystyrene.

### Synthesis Example 2

In Synthesis Example 2, a polymetalloxane (PM-2) solution was synthesized. Specifically, 28.61 g (0.08 mol) of tri-n-propoxy(trimethylsiloxy)zirconium, 5.25 g of (0.02 mol) of di-s-butoxy(trimethylsiloxy)aluminum, and 28.49 g of DMIB as a solvent were mixed to obtain a solution 1. In addition, 5.04 g (0.28 mol) of water, 50.0 g of IPA as a water-diluted solvent, and 1.85 g (0.01 mol) of tributylamine as a polymerization catalyst were mixed to obtain a solution 2.

In the same manner as in Synthesis Example 1, hydrolysis and polycondensation were performed. During the reaction, IPA, n-propanol, 2-butanol, and water were distilled. During heating with stirring, precipitation did not occur in the liquid in the flask, and it was a uniform transparent solution.

After completion of the heating, the liquid in the flask was cooled to room temperature to obtain a polymetalloxane solution. The appearance of the polymetalloxane solution obtained was pale yellow transparent. The solid component concentration of the polymetalloxane solution obtained was 39.4 mass %. Then, DMIB was added such that the solid component concentration became 20.0 mass % to obtain a polymetalloxane (PM-2) solution.

Analysis of the polymetalloxane (PM-2) solution by FT-IR revealed that an absorption peak of Zr—O—Si (968 cm⁻¹) and an absorption peak of Al—O—Si (780 cm⁻¹) were observed, and thus the polymetalloxane was a polymetalloxane having a trimethylsiloxy group. The weight-average molecular weight (Mw) of the polymetalloxane (PM-2) was 470,000 in terms of polystyrene.

### Synthesis Example 3

In Synthesis Example 3, a polymetalloxane (PM-3) solution was synthesized. Specifically, 17.88 g (0.05 mol) of tri-n-propoxy(trimethylsiloxy)zirconium, 13.12 g of (0.05 mol) of di-s-butoxy(trimethylsiloxy)aluminum, and 25.24 g of DMIB as a solvent were mixed to obtain a solution 1. In addition, 4.50 g (0.25 mol) of water, 50.0 g of IPA as a water-diluted solvent, and 1.85 g (0.01 mol) of tributylamine as a polymerization catalyst were mixed to obtain a solution 2.

In the same manner as in Synthesis Example 1, hydrolysis and polycondensation were performed. During the reaction, IPA, n-propanol, 2-butanol, and water were distilled. During heating with stirring, precipitation did not occur in the liquid in the flask, and it was a uniform transparent solution.

After completion of the heating, the liquid in the flask was cooled to room temperature to obtain a polymetalloxane solution. The appearance of the polymetalloxane solution obtained was pale yellow transparent. The solid component concentration of the polymetalloxane solution obtained was 38.2 mass %. Then, DMIB was added such that the solid component concentration became 20.0 mass % to obtain a polymetalloxane (PM-3) solution.

Analysis of the polymetalloxane (PM-3) solution by FT-IR revealed that an absorption peak of Zr—O—Si (968 cm⁻¹) and an absorption peak of Al—O—Si (780 cm⁻¹) were observed, and thus the polymetalloxane was a polymetalloxane having a trimethylsiloxy group. The weight-average molecular weight (Mw) of the polymetalloxane (PM-3) was 400,000 in terms of polystyrene.

### Synthesis Example 4

In Synthesis Example 4, a polymetalloxane (PM-4) solution was synthesized. Specifically, 7.15 g (0.02 mol) of tri-n-propoxy(trimethylsiloxy)zirconium, 20.99 g of (0.08 mol) of di-s-butoxy(trimethylsiloxy)aluminum, and 20.99 g of DMIB as a solvent were mixed to obtain a solution 1. In addition, 3.96 g (0.22 mol) of water, 50.0 g of IPA as a water-diluted solvent, and 1.85 g (0.01 mol) of tributylamine as a polymerization catalyst were mixed to obtain a solution 2.

In the same manner as in Synthesis Example 1, hydrolysis and polycondensation were performed. During the reaction, IPA, n-propanol, 2-butanol, and water were distilled. During heating with stirring, precipitation did not occur in the liquid in the flask, and it was a uniform transparent solution.

After completion of the heating, the liquid in the flask was cooled to room temperature to obtain a polymetalloxane solution. The appearance of the polymetalloxane solution obtained was pale yellow transparent. The solid component concentration of the polymetalloxane solution obtained was 35.0 mass %. Then, DMIB was added such that the solid component concentration became 20.0 mass % to obtain a polymetalloxane (PM-4) solution.

Analysis of the polymetalloxane (PM-4) solution by FT-IR revealed that an absorption peak of Zr—O—Si (968 cm⁻¹) and an absorption peak of Al—O—Si (780 cm⁻¹) were observed, and thus the polymetalloxane was a polymetalloxane having a trimethylsiloxy group. The weight-average molecular weight (Mw) of the polymetalloxane (PM-4) was 337,000 in terms of polystyrene.

### Synthesis Example 5

In Synthesis Example 5, a polymetalloxane (PM-5) solution was synthesized. Specifically, 26.24 g of (0.10 mol) of di-s-butoxy(trimethylsiloxy)aluminum and 19.82 g of DMIB as a solvent were mixed to obtain a solution 1. In addition, 3.60 g (0.20 mol) of water, 50.0 g of IPA as a water-diluted solvent, and 1.85 g (0.01 mol) of tributylamine as a polymerization catalyst were mixed to obtain a solution 2.

In the same manner as in Synthesis Example 1, hydrolysis and polycondensation were performed. During the reaction, IPA, 2-butanol, and water were distilled. During heating with stirring, precipitation did not occur in the liquid in the flask, and it was a uniform transparent solution.

After completion of the heating, the liquid in the flask was cooled to room temperature to obtain a polymetalloxane solution. The appearance of the polymetalloxane solution obtained was pale yellow transparent. The solid component concentration of the polymetalloxane solution obtained was 32.2 mass %. Then, DMIB was added such that the solid component concentration became 20.0 mass % to obtain a polymetalloxane (PM-5) solution.

Analysis of the polymetalloxane (PM-5) solution by FT-IR revealed that an absorption peak of Al—O—Si (780 cm⁻¹) was observed, and thus the polymetalloxane was a polymetalloxane having a trimethylsiloxy group. The weight-average molecular weight (Mw) of the polymetalloxane (PM-4) was 190,000 in terms of polystyrene.

### Synthesis Example 6

In Synthesis Example 6, a polymetalloxane (PM-6) solution was synthesized. Specifically, 19.18 g (0.05 mol) of tetra-n-butoxy zirconium, 12.32 g (0.05 mol) of tri-s-butoxy aluminum, and 50.70 g of DMIB as a solvent were mixed to obtain a solution 1. In addition, 2.70 g (0.15 mol) of water, 50.0 g of IPA as a water-diluted solvent, and 0.25 g (0.002 mol) of t-butylhydrazine hydrochloride as a polymerization catalyst were mixed to obtain a solution 2.

In the same manner as in Synthesis Example 1, hydrolysis and polycondensation were performed. During the reaction, IPA, 2-butanol, water, and n-butanol were distilled. During heating with stirring, precipitation did not occur in the liquid in the flask, and it was a uniform transparent solution.

After completion of the heating, the liquid in the flask was cooled to room temperature to obtain a polymetalloxane solution. The appearance of the polymetalloxane solution obtained was pale yellow transparent. The solid component concentration of the polymetalloxane solution obtained was 28.2 mass %. Then, DMIB was added such that the solid component concentration became 20.0 mass % to obtain a polymetalloxane (PM-6) solution.

The weight-average molecular weight (Mw) of the polymetalloxane (PM-6) was 7,800 in terms of polystyrene.

Synthesis Examples 1 to 6 are collectively tabulated in Table 1.

TABLE 1

| | | | | | | | | | | Polymer properties | | |
|---|---|---|---|---|---|---|---|---|---|---|---|---|
| | | | | | | | | | | Solid | Solid | Weight- |
| | | Solution 1 | | | | | Solution 2 | | | component | component | average |
| | | Metal alkoxide 1 | | Metal alkoxide 2 | | | | Water- | Poly- | concentration | concentration | molecular |
| | | | Addition | | Addition | | | diluted | merization | after poly- | after | weight |
| | | Type | amount | Type | amount | Solvent | Water | solvent | catalyst | merization | adjustment | (Mw) |
| Synthesis | Poly- | Tri-n- | 35.77 g | — | — | DMIB | 5.40 g | IPA | Tributyl- | 39.8% | 20.0% | 500,000 |
| Example | metalloxane | propoxy | (0.10 | | | 30.66 g | (0.30 | 50 g | amine | | | |
| 1 | (PM-1) | (trimethyl- | mol) | | | | mol) | | 1.85 g | | | |
| | solution | siloxy) | | | | | | | (0.01 mol) | | | |
| | | zirconium | | | | | | | | | | |
| Synthesis | Poly- | Tri-n- | 28.61 g | Di-s- | 5.25 g | DMIB | 5.04 g | IPA | Tributyl- | 39.4% | 20.0% | 470,000 |
| Example | metalloxane | propoxy | (0.08 | butoxy | (0.02 | 28.49 g | (0.28 | 50 g | amine | | | |
| 2 | (PM-2) | (trimethyl- | mol) | (trimethyl- | mol) | | mol) | | 1.85 g | | | |
| | solution | siloxy) | | siloxy) | | | | | (0.01 mol) | | | |
| | | zirconium | | aluminum | | | | | | | | |
| Synthesis | Poly- | Tri-n- | 17.88 g | Di-s- | 13.12 g | DMIB | 4.50 g | IPA | Tributyl- | 38.2% | 20.0% | 400,000 |
| Example | metalloxane | propoxy | (0.05 | butoxy | (0.05 | 25.24 g | (0.25 | 50 g | amine | | | |
| 3 | (PM-3) | (trimethyl- | mol) | (trimethyl- | mol) | | mol) | | 1.85 g | | | |
| | solution | siloxy) | | siloxy) | | | | | (0.01 mol) | | | |
| | | zirconium | | aluminum | | | | | | | | |
| Synthesis | Poly- | Tri-n- | 7.15 g | Di-s- | 20.99 g | DMIB | 3.96 g | IPA | Tributyl- | 35.0% | 20.0% | 337,000 |
| Example | metalloxane | propoxy | (0.02 | butoxy | (0.08 | 21.99 g | (0.22 | 50 g | amine | | | |
| 4 | (PM-4) | (trimethyl- | mol) | (trimethyl- | mol) | | mol) | | 1.85 g | | | |
| | solution | siloxy) | | siloxy) | | | | | (0.01 mol) | | | |
| | | zirconium | | aluminum | | | | | | | | |
| Synthesis | Poly- | — | — | Di-s- | 26.24 g | DMIB | 3.60 g | IPA | Tributyl- | 32.2% | 20.0% | 190,000 |
| Example | metalloxane | | | butoxy | (0.10 | 19.82 g | (0.20 | 50 g | amine | | | |
| 5 | (PM-5) | | | (trimethyl- | mol) | | mol) | | 1.85 g | | | |
| | solution | | | siloxy) | | | | | (0.01 mol) | | | |
| | | | | aluminum | | | | | | | | |
| Synthesis | Poly- | tetra-n- | 19.18 g | Tri-s- | 12.32 g | DMIB | 2.70 g | IPA | t-Butyl- | 28.2% | 20.0% | 7,800 |
| Example | metalloxane | butoxy | (0.05 | butoxy | (0.05 | 50.70 g | (0.15 | 50 g | hydrazine | | | |
| 6 | (PM-6) | zirconium | mol) | aluminum | mol) | | mol) | | hydro- | | | |
| | solution | | | | | | | | chloride | | | |
| | | | | | | | | | 0.25 g | | | |
| | | | | | | | | | (0.002 mol) | | | |

### Example 1

(I) Production of Heat-Treated Film Containing Polymetalloxane

A polymetalloxane solution (PM-1) was applied by spin coating to a 4-inch silicon wafer as a substrate using a spin coater (1H-360S manufactured by Mikasa Corporation), and then heated at 100° C. for 5 minutes using a hot plate (SCW-636, manufactured by Dainippon Screen Mfg. Co., Ltd.) to produce a coating film having a film thickness of 0.50 μm. Here, the film thickness was measured using a spectroscopic reflectometer (Lambda Ace STM602, manufactured by Dainippon Screen Mfg. Co., Ltd.).

The coating film obtained in the coating step was heated at 300° C. for 5 minutes using a hot plate (SCW-636, manufactured by Dainippon Screen Mfg. Co., Ltd.) to produce a heat-treated film. The film thickness of the heat-treated film was 0.30 μm. The film density of the heat-treated film was 2.33 g/cm³. The film stress of the heat-treated film was 101.0 MPa.

(II) Evaluation of Etching Resistance

Using a reactive ion etching apparatus (RIE-10N manufactured by Samco Inc.), the whole face of the heat-treated film obtained in the above-mentioned (I) was dry-etched using a process gas that was a gas mixture of CF₄ (methane tetrafluoride) and oxygen. The dry-etching conditions were as follows: a gas mixture ratio of 80:20 as CF₄:oxygen; a gas flow rate of 50 sccm; an output of 199 W; an internal pressure of 10 Pa; and a treatment time of 5 min. The thickness of the film dry-etched was measured, and a difference in the thickness of the film between before and after the dry-etching was divided by the dry-etching time to calculate the rate of etching.

(III) Evaluation of Peelability

The heat-treated film obtained in the above-mentioned (I) was immersed at 25° C. for 2 minutes in a peeling liquid that was a solution mixture of H₃PO₄/HNO₃/CH₃COOH/H₂O mixed at a ratio of 65/3/5/27 (by weight). The thickness of the film immersed was measured, and a difference in the thickness of the film between before and after the immersion was determined.

### Examples 2 to 10

In accordance with the conditions mentioned in the below-mentioned Table 2, (II) the evaluation of etching resistance and (III) the evaluation of peelability were performed by the same methods as in Example 1. The evaluation results are tabulated in Table 2.

With respect to (II) the evaluation of etching resistance, it can be said that the lower the rate of etching is, the higher the etching resistance is. The rate of etching is preferably 100 nm/minute or less, more preferably 30 nm/minute or less, most preferably 5 nm/minute or less. Such a higher etching resistance makes the mask less prone to be shaved when the inorganic solid is patterned by etching using a pattern of a heat-treated film as a mask. Thus, the inorganic solid pattern can be made deeper.

With respect to (III) the evaluation of peelability, it can be said that the larger the rate of dissolution is, the higher (better) the peelability is. The rate of dissolution is preferably 10 nm/minute or more, more preferably 40 nm/minute or more, most preferably 80 nm/minute or more. Such a higher peelability makes it possible to shorten the time while the heat-treated film is immersed in the peeling liquid for the pattern of the heat-treated film to be peeled off, and thus, makes it possible to shorten the process time further.

### Example 11

(I) Production of Heat-Treated Film Containing Polymetalloxane

A polymetalloxane solution (PM-6) was applied by spin coating to a 4-inch silicon wafer as a substrate using a spin coater (1H-360S manufactured by Mikasa Corporation), and then heated at 100° C. for 5 minutes using a hot plate (SCW-636, manufactured by Dainippon Screen Mfg. Co., Ltd.) to produce a coating film having a film thickness of 0.20 μm.

The coating film obtained in the coating step was heated at 500° C. for 5 minutes using a hot plate (SCW-636, manufactured by Dainippon Screen Mfg. Co., Ltd.) to produce a heat-treated film. The film thickness of the heat-treated film was 0.08 μm. The film density of the heat-treated film was 2.65 g/cm³. The film stress of the heat-treated film was 74.6 MPa.

(II) the evaluation of etching resistance and (III) the evaluation of peelability were performed by the same methods as in Example 1. The evaluation results are tabulated in Table 2.

### Example 12

(I) Production of Heat-Treated Film Containing Polymetalloxane

A polymetalloxane solution (PM-4) was applied by spin coating to a 4-inch silicon wafer as a substrate using a spin coater (1H-360S manufactured by Mikasa Corporation), and then heated at 100° C. for 5 minutes using a hot plate (SCW-636, manufactured by Dainippon Screen Mfg. Co., Ltd.) to produce a coating film having a film thickness of 0.80 μm.

The coating film obtained in the coating step was heated at 500° C. for 5 minutes using a hot plate (SCW-636, manufactured by Dainippon Screen Mfg. Co., Ltd.) to produce a heat-treated film. The film thickness of the heat-treated film was 0.50 μm.

To the heat-treated film obtained, the polymetalloxane (PM-4) solution was applied again by spin coating in the same manner, heated at 100° C. for 5 minutes, and heated at 500° C. for 5 minutes to produce a heat-treated film having a thickness of 0.50 μm. Thus, the heat-treated film became 1.00 nm in total.

(II) the evaluation of etching resistance and (III) the evaluation of peelability were performed by the same methods as in Example 1. The evaluation results are tabulated in Table 2.

TABLE 2

| | | | | | | (II) Evaluation of | | (III) Evaluation | |
|---|---|---|---|---|---|---|---|---|---|
| (I) Production of cured film containing polymetalloxane | | | | | | etching resistance | | of peelability | |
| | | Heat | Thickness | Film | | Thickness | | Thickness | |
| | Type of | treatment | of cured | density | Stress | of film | Rate of | of film | Rate of |
| | solution | temperature | film | [g/cm³] | [MPa] | etched | etching | peeled | dissolution |
| Example 1 | Polymetalloxane | 300° C. | 0.30 μm | 2.33 | 101.0 | 0.30 μm | 0 nm/min | 0.20 μm | 50 nm/min |
| | (PM-1) solution | | | | | | | | |
| Example 2 | Polymetalloxane | 300° C. | 0.30 μm | 2.17 | 65.0 | 0.30 μm | 0 nm/min | 0.10 μm | 100 nm/min |
| | (PM-2) solution | | | | | | | | |
| Example 3 | Polymetalloxane | 300° C. | 0.30 μm | 1.93 | 44.6 | 0.30 μm | 0 nm/min | 0.00 μm | >150 nm/min |
| | (PM-3) solution | | | | | | | (all dissolved) | |
| Example 4 | Polymetalloxane | 300° C. | 0.30 μm | 1.73 | 64.0 | 0.28 μm | 4 nm/min | 0.00 μm | >150 nm/min |
| | (PM-4) solution | | | | | | | (all dissolved) | |
| Example 5 | Polymetalloxane | 300° C. | 0.30 μm | 1.62 | 79.2 | 0.25 μm | 10 nm/min | 0.00 μm | >150 nm/min |
| | (PM-5) solution | | | | | | | (all dissolved) | |
| Example 6 | Polymetalloxane | 500° C. | 0.20 μm | 3.31 | 126.5 | 0.20 μm | 0 nm/min | 0.14 μm | 30 nm/min |
| | (PM-1) solution | | | | | | | | |
| Example 7 | Polymetalloxane | 500° C. | 0.20 μm | 3.03 | 90.0 | 0.20 μm | 0 nm/min | 0.10 μm | 50 nm/min |
| | (PM-2) solution | | | | | | | | |
| Example 8 | Polymetalloxane | 500° C. | 0.20 μm | 2.62 | 59.2 | 0.20 μm | 0 nm/min | 0.04 μm | 80 nm/min |
| | (PM-3) solution | | | | | | | | |
| Example 9 | Polymetalloxane | 500° C. | 0.20 μm | 2.21 | 51.6 | 0.20 μm | 0 nm/min | 0.00 μm | >100 nm/min |
| | (PM-4) solution | | | | | | | (all dissolved) | |
| Example 10 | Polymetalloxane | 500° C. | 0.20 μm | 1.93 | 47.6 | 0.20 μm | 0 nm/min | 0.00 μm | >100 nm/min |
| | (PM-5) solution | | | | | | | (all dissolved) | |
| Example 11 | Polymetalloxane | 500° C. | 0.08 μm | 2.65 | 74.6 | 0.08 μm | 0 nm/min | 0.00 μm | >40 nm/min |
| | (PM-6) solution | | | | | | | (all dissolved) | |
| Example 12 | Polymetalloxane | 500° C. | 1.00 μm | 2.21 | 51.6 | 1.00 μm | 0 nm/min | 0.60 μm | 200 nm/min |
| | (PM-4) solution | | | | | | | | |

### Example 13

On a 4-inch silicon wafer as a substrate, an SiO₂ layer was formed using a sputtering apparatus (SH-450, manufactured by ULVAC, Inc.) and using SiO₂ as a target. The sputtering conditions were as follows: Ar as a process gas; a gas flow rate of 20 sccm; an output of 1000 W; an internal pressure of 0.2 Pa; and a treatment time of 150 min. The film thickness of the SiO₂ layer was 0.50 μm.

To the SiO₂ layer formed, a polymetalloxane solution (PM-3) was applied by spin coating using a spin coater (1H-360S manufactured by Mikasa Corporation), and then heated at 100° C. for 5 minutes using a hot plate (SCW-636, manufactured by Dainippon Screen Mfg. Co., Ltd.) to produce a coating film having a film thickness of 0.50 μm.

The coating film obtained in the coating step was heated at 500° C. for 5 minutes using a hot plate (SCW-636, manufactured by Dainippon Screen Mfg. Co., Ltd.) to produce a heat-treated film. The film thickness of the heat-treated film was 0.2 μm.

To the heat-treated film, a positive type photoresist (OFPR-800, manufactured by Tokyo Ohka Kogyo Co., Ltd.) was applied by spin coating, and then heated at 100° C. for 2 minutes using a hot plate to form a photoresist layer. Thereafter, pattern exposure was performed through a mask using an i-line stepper (NSR-i9C, manufactured by Nikon Corporation). As a mask, a mask designed to obtain a 1.0 μm hole-shaped pattern was used.

Thereafter, using an automatic developing apparatus (AD-2000, manufactured by Takizawa Co., Ltd.), shower development with an aqueous 2.38 wt % solution of tetramethylammonium hydroxide as a developer was performed for 90 seconds, followed by rinsing with water for 30 seconds to obtain a 1.0 μm hole-shaped photoresist pattern.

The heat-treated film containing a photoresist pattern and a polymetalloxane was dry-etched using a reactive ion etching apparatus (RIE-200iPC, manufactured by Samco Inc.) and using a process gas that was a gas mixture of boron trichloride (BCl₃), chlorine (Cl₂), and argon (Ar). Thus, a pattern of the heat-treated film containing a polymetalloxane was obtained. The dry-etching conditions were as follows: a gas mixture ratio of 10:60:30 as BCl₃:Cl₂:Ar; a gas flow rate of 55 sccm; an output of 250 W; an internal pressure of 0.6 Pa; and a treatment time of 10 min.

Using a reactive ion etching apparatus (RIE-10N manufactured by Samco Inc.), the whole face of the heat-treated film pattern obtained and the inorganic solid were dry-etched using a process gas that was a gas mixture of CF₄ (methane tetrafluoride) and oxygen. The dry-etching conditions were as follows: a gas mixture ratio of 80:20 as CF₄:oxygen; a gas flow rate of 50 sccm; an output of 199 W; an internal pressure of 10 Pa; and a treatment time of 5 min. Then, the substrate was immersed in a solution mixture of H₃PO₄/HNO₃/CH₃COOH/H₂O mixed at a ratio of 65/3/5/27 (by weight), whereby the heat-treated film pattern was removed. Thus, an inorganic solid pattern was obtained.

The inorganic solid pattern obtained was an SiO₂ layer having a film thickness of 0.50 μm, in which a hole-shaped pattern having a pattern depth of 0.50 μm and a pattern width of 1.0 μm was formed.

### Example 14

An inorganic solid pattern was formed in the same manner as in the step of forming an inorganic solid in Example 13 except that the target was changed from SiO₂ to Si₃N₄ to form an Si₃N₄ layer. The film thickness of the Si₃N₄ layer was 0.50 μm. The inorganic solid pattern obtained was an Si₃N₄ layer having a film thickness of 0.50 μm, in which a hole-shaped pattern having a pattern depth of 0.50 μm and a pattern width of 1 μm was formed.

### Example 15

An inorganic solid pattern was formed in the same manner as in the step of forming an inorganic solid in Example 13 except that SiO₂ and Si₃N₄ were sequentially formed as inorganic solids to obtain a two-layered laminate of an SiO₂ layer and an Si₃N₄ layer. The inorganic solid pattern obtained was a laminate composed of an SiO₂ layer and an Si₃N₄ layer and having a total film thickness of 1.0 μm, in which a hole-shaped pattern having a pattern depth of 0.50 μm and a pattern width of 1 μm was formed.

In Examples 13 to 15, etching the inorganic solid using the polymetalloxane (PM-3) as an etching mask made it possible to obtain an inorganic solid pattern having a high aspect ratio. This is because the polymetalloxane (PM-3) had high etching resistance as demonstrated in Example 3 and Example 8. Accordingly, it is understand that using a polymetalloxane having high etching resistance makes it possible to obtain an inorganic solid pattern having a high aspect ratio.

### Example 16

On a 4-inch silicon wafer as a substrate, an SiO₂ layer was formed using a sputtering apparatus (SH-450, manufactured by ULVAC, Inc.) and using SiO₂ as a target. The sputtering conditions were as follows: Ar as a process gas; a gas flow rate of 20 sccm; an output of 1000 W; an internal pressure of 0.2 Pa; and a treatment time of 15 min. The film thickness of the SiO₂ layer was 0.05 μm.

Then, the target was changed from SiO₂ to Si₃N₄, and an Si₃N₄ layer was formed. The sputtering conditions were as follows: Ar as a process gas; a gas flow rate of 20 sccm; an output of 1000 W; an internal pressure of 0.2 Pa; and a treatment time of 15 min. The film thickness of the Si₃N₄ layer was 0.05 μm, and the thickness of the whole laminate of the SiO₂ layer and the Si₃N₄ layer was 0.10 μm.

Then, the formation of SiO₂ and the formation of an Si₃N₄ layer were repeated until the SiO₂ layer and the Si₃N₄ layer, 100 layers each, were formed. The film thickness of the whole of the resulting laminate of the SiO₂ layer and the Si₃N₄ layer was 10.0 μm.

To the laminate formed of the SiO₂ layer and the Si₃N₄ layer, a polymetalloxane solution (PM-3) was applied by spin coating using a spin coater (1H-360S manufactured by Mikasa Corporation), and then heated at 100° C. for 5 minutes using a hot plate (SCW-636, manufactured by Dainippon Screen Mfg. Co., Ltd.) to produce a coating film having a film thickness of 0.50 μm.

The coating film obtained in the coating step was heated at 500° C. for 5 minutes using a hot plate (SCW-636, manufactured by Dainippon Screen Mfg. Co., Ltd.) to produce a heat-treated film. The film thickness of the heat-treated film was 0.2 μm.

To the heat-treated film, a positive type photoresist (OFPR-800, manufactured by Tokyo Ohka Kogyo Co., Ltd.) was applied by spin coating, and then heated at 100° C. for 2 minutes using a hot plate to form a photoresist layer. Thereafter, pattern exposure was performed through a mask using an i-line stepper (NSR-i9C, manufactured by Nikon Corporation). As a mask, a mask designed to obtain a 1.0 μm hole-shaped pattern was used.

Thereafter, using an automatic developing apparatus (AD-2000, manufactured by Takizawa Co., Ltd.), shower development with an aqueous 2.38 wt % solution of tetramethylammonium hydroxide as a developer was performed for 90 seconds, followed by rinsing with water for 30 seconds to obtain a 1.0 μm hole-shaped photoresist pattern.

The heat-treated film containing a photoresist pattern and a polymetalloxane was dry-etched using a reactive ion etching apparatus (RIE-200iPC, manufactured by Samco Inc.) and using a process gas that was a gas mixture of boron trichloride (BCl₃), chlorine (Cl₂), and argon (Ar). Thus, a pattern of the heat-treated film containing a polymetalloxane was obtained. The dry-etching conditions were as follows: a gas mixture ratio of 10:60:30 as BCl₃:Cl₂:Ar; a gas flow rate of 55 sccm; an output of 250 W; an internal pressure of 0.6 Pa; and a treatment time of 10 min.

Using a reactive ion etching apparatus (RIE-10N manufactured by Samco Inc.), the whole face of the heat-treated film pattern obtained and the inorganic solid were dry-etched using a process gas that was a gas mixture of CF₄ (methane tetrafluoride) and oxygen. The dry-etching conditions were as follows: a gas mixture ratio of 80:20 as CF₄:oxygen; a gas flow rate of 50 sccm; an output of 199 W; an internal pressure of 10 Pa; and a treatment time of 500 min. Then, the substrate was immersed in a solution mixture of H₃PO₄/HNO₃/CH₃COOH/H₂O mixed at a ratio of 65/3/5/27 (by weight), whereby the heat-treated film pattern was removed. Thus, an inorganic solid pattern was obtained.

The inorganic solid pattern obtained was an SiO₂ layer having a film thickness of 10.0 μm, in which a hole-shaped pattern having a pattern depth of 10.0 μm and a pattern width of 1.0 μm was formed.

### INDUSTRIAL APPLICABILITY

As above-mentioned, a method of producing an inorganic solid pattern and an inorganic solid pattern according to the present invention are suitable to easily produce an inorganic solid pattern having a high aspect ratio.

1. A method of producing an inorganic solid pattern, comprising:
a coating step of coating an inorganic solid with a composition containing a polymetalloxane and an organic solvent;
a step of heating a coating film obtained in said coating step, at a temperature of 100° C. or more and 1000° C. or less to form said coating film into a heat-treated film;
a step of forming a pattern of said heat-treated film; and
a step of patterning said inorganic solid by etching using said pattern of said heat-treated film as a mask.

2. The method of producing an inorganic solid pattern according to claim 1,
wherein said polymetalloxane contains a repeating structure of the following: a metal atom selected from the group consisting of Al, Sc, Ti, V, Cr, Mn, Fe, Co, Ni, Cu, Zn, Ga, Ge, Y, Zr, Nb, Mo, Pd, Ag, In, Sn, Sb, Hf, Ta, W, and Bi; and an oxygen atom.

3. The method of producing an inorganic solid pattern according to claim 2, wherein said repeating structure of a metal atom and an oxygen atom in said polymetalloxane contains one or more metal atoms selected from the group consisting of Al, Ti, Zr, Hf, and Sn.

4. The method of producing an inorganic solid pattern according to claim 1,
wherein said repeating structure of a metal atom and an oxygen atom in said polymetalloxane contains the metal atoms of Al and Zr.

5. The method of producing an inorganic solid pattern according to claim 1,
wherein said repeating structure of a metal atom and an oxygen atom in the polymetalloxane contains the metal atoms of Al and Zr, and
wherein the ratio of said Al in all the metal atoms in said polymetalloxane is 10 mol % or more and 90 mol % or less, and the ratio of said Zr in all the metal atoms in said polymetalloxane is 10 mol % or more and 90 mol % or less.

6. The method of producing an inorganic solid pattern according to claim 1,
wherein said repeating structure of a metal atom and an oxygen atom in the polymetalloxane contains the metal atoms of Al and Zr, and
wherein the ratio of said Al in all the metal atoms in said polymetalloxane is 30 mol % or more and 70 mol % or less, and the ratio of said Zr in all the metal atoms in said polymetalloxane is 30 mol % or more and 70 mol % or less.

7. The method of producing an inorganic solid pattern according to claim 1,
wherein the inorganic solid contains SiO₂ or Si₃N₄.

8. The method of producing an inorganic solid pattern according to claim 1,
wherein said inorganic solid is constituted by one or more materials selected from the group consisting of SiO₂, Si₃N₄, Al₂O₃, TiO₂, ZrO₂, SiC, GaN, GaAs, InP, AlN, TaN, LiTaO₃, BN, TiN, BaTiO₃, InO₃, SnO₂, ZnS, ZnO, WO₃, MoO₃, and Si.

9. The method of producing an inorganic solid pattern according to claim 1,
wherein said polymetalloxane has a weight-average molecular weight of 10,000 or more and 2,000,000 or less.

10. The method of producing an inorganic solid pattern according to claim 1, wherein said polymetalloxane has a repeating structural unit represented by the following general formula: 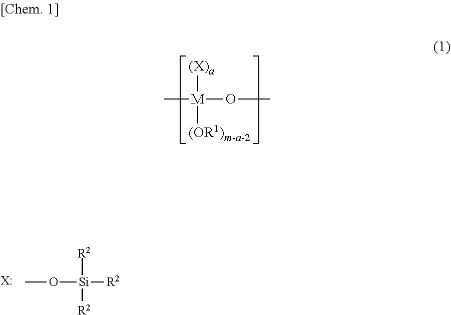
(wherein M represents a metal atom selected from the group consisting of Al, Sc, Ti, V, Cr, Mn, Fe, Co, Ni, Cu, Zn, Ga, Ge, Y, Zr, Nb, Mo, Pd, Ag, In, Sn, Sb, Hf, Ta, W, and Bi; R¹ is arbitrarily selected from a hydrogen atom, an alkyl group having 1 to 12 carbon atoms, or a group having a metalloxane bond; R² is arbitrarily selected from a hydroxy group, an alkyl group having 1 to 12 carbon atoms, an alicyclic alkyl group having 5 to 12 carbon atoms, an alkoxy group having 1 to 12 carbon atoms, an aromatic group having 6 to 30 carbon atoms, a group having a siloxane bond, or a group having a metalloxane bond; when a plurality of R¹s and a plurality of R²s exist, the R¹s and the R²s may be the same or different; m is an integer representing the valence of the metal atom M; and a is an integer of 1 to (m−2)).

11. The method of producing an inorganic solid pattern according to claim 1,
wherein said inorganic solid is constituted by one or more materials selected from the group consisting of SiO₂, Si₃N₄, Al₂O₃, TiO₂, and ZrO₂.

12. The method of producing an inorganic solid pattern according to claim 1,
wherein said inorganic solid is a laminate of a plurality of inorganic solid layers.

13. (canceled)

14. (canceled)

15. (canceled)

16. (canceled)
